(19) United States
(12) Patent Application Publication
(10) Pub. No.: US 2024/0015879 A1
(43) Pub. Date: Jan. 11, 2024

(54) PLASMA DEVICE

(71) Applicant: NATIONAL CHENG KUNG UNIVERSITY, TAINAN CITY (TW)

(72) Inventors: Yu Chi CHANG, Tainan City (TW); Zhao-Cheng CHEN, Kaohsiung City (TW)

(21) Appl. No.: 18/186,967

(22) Filed: Mar. 21, 2023

(30) Foreign Application Priority Data
Jul. 5, 2022 (TW) 111125187

(51) Int. Cl. H05H 1/46; H01J 37/32; C23C 16/505; C23C 16/455

(52) U.S. Cl. CPC H05H 1/466; H01J 37/32541; C23C 16/505; C23C 16/45536; H01J 2237/332

(57) ABSTRACT

A plasma device includes a hollow chamber casing, at least one hollow electrode tube, and an intermediate frequency plasma power supply. The hollow chamber casing has a chamber. The at least one hollow electrode tube is disposed within the chamber, in which a tube wall of the at least one hollow electrode tube is provided with several holes. The intermediate frequency plasma power supply has a first potential terminal and a second potential terminal. The first potential terminal and the second potential terminal have different potentials. The first potential terminal and the second potential terminal are respectively connected to the hollow chamber casing and the at least one hollow electrode tube.

### RELATED APPLICATIONS

This application claims priority to Taiwan Application Serial Number 111125187, filed Jul. 5, 2022, which is herein incorporated by reference.

### BACKGROUND

### Field of Invention

The present disclosure relates to a plasma technology, and more particularly, to a plasma device using an intermediate frequency plasma power supply.

### Description of Related Art

Most of the plasma dissociation devices in the atomic layer deposition (ALD) apparatuses on the market today are inductively coupled plasma (ICP) devices. Typically, the inductively coupled plasma device mainly generates plasma by wrapping an induction coil on an outside of a quartz tube and using a ratio frequency (RF) plasma power at 13.56 MHz. A plasma density of the inductively coupled plasma device can reach 10¹¹ cm⁻³ to about 10¹² cm⁻³.

However, the inductively coupled plasma device must be equipped with a radio frequency plasma power supply, and the commercially available radio frequency plasma power supply is expensive, which results in high cost, such that it is difficult for small and medium enterprises or academic research units to afford. In addition, the radio frequency plasma power supply has the problem of signal interference, and it is difficult to install multiple sets of plasma sources, such that it cannot be applied to large-area coating.

### SUMMARY

Therefore, one objective of the disclosure is to provide a plasma device, which includes a hollow electrode tube with holes and an intermediate frequency plasma power supply, and can generate a plasma density of about 10¹⁰ cm⁻³ to about 10¹¹ cm⁻³. The price of the intermediate frequency plasma power supply is much lower than that of the radio frequency plasma power supply, such that the plasma device of the present disclosure can greatly reduce the apparatus cost while providing the plasma density similar to that of the inductively coupled plasma device.

Another objective of the present disclosure is to provide a plasma device, which can generate a plasma density not inferior to that of an inductively coupled plasma device by using an intermediate frequency plasma power supply. There is no mutual interference between the intermediate frequency plasma power supplies, such that the coating apparatus can be equipped with multiple sets of plasma devices at the same time, which is conducive to the enhancement of productivity and suitable for large-area coating.

According to the above objectives, the present disclosure provides a plasma device. The plasma device includes a hollow chamber casing, at least one hollow electrode tube, and an intermediate frequency plasma power supply. The hollow chamber casing has a chamber. The at least one hollow electrode tube is disposed in the chamber, in which a tube wall of the at least one hollow electrode tube is provided with plural holes. The intermediate frequency plasma power supply has a first potential terminal and a second potential terminal. The first potential terminal and the second potential terminal have different potentials. The first potential terminal and the second potential terminal are respectively connected to the hollow chamber casing and the at least one hollow electrode tube.

According to one embodiment of the present disclosure, the at least one hollow electrode tube is a hollow cathode discharge (HCD).

According to one embodiment of the present disclosure, the at least one hollow electrode tube includes plural hollow electrode tubes.

According to one embodiment of the present disclosure, diameters of the holes are identical.

According to one embodiment of the present disclosure, diameters of the holes are not all the same.

According to one embodiment of the present disclosure, shapes of the holes are round, oval, strip, or irregular.

According to one embodiment of the present disclosure, the at least one hollow electrode tube is made from a conductive material.

According to one embodiment of the present disclosure, a frequency of the intermediate frequency plasma power supply is about 1 Hz to about 500 kHz.

According to one embodiment of the present disclosure, the first potential terminal is a high voltage output terminal, and the second potential terminal is a ground terminal or has a potential lower than a potential of the first potential terminal, which can constitute a condition for generating plasma.

According to one embodiment of the present disclosure, the plasma device is a capacitively coupled plasma (CCP) device.

### BRIEF DESCRIPTION OF THE DRAWINGS

In order to make the above and other objectives, features, advantages, and embodiments of the present disclosure more comprehensible, the accompanying drawings are described as follows:

FIG. 1 is a schematic cross-sectional view of a plasma device in accordance with one embodiment of the present disclosure; and

FIG. 2 is a three-dimensional schematic diagram showing a hollow electrode tube of a plasma device in accordance with one embodiment of the present disclosure.

### DETAILED DESCRIPTION

The radio frequency plasma power supply of the inductively coupled plasma device is too expensive, and the radio frequency plasma power supply has the signal interference problem, such that it is difficult to install multiple sets of plasma sources at the same time. Therefore, the present disclosure herein provides a plasma device that utilizes capacitively coupled plasma to generate plasma, and can generate a plasma density similar to that of an inductively coupled plasma device by using an intermediate frequency plasma power supply instead of a radio frequency plasma power supply. Accordingly, the cost of the plasma device of the present disclosure is much lower than that of the inductively coupled plasma device, and one plasma device can be equipped with multiple sets of plasma devices at the same time, which is beneficial to the increase of productivity and suitable for large-area coating.

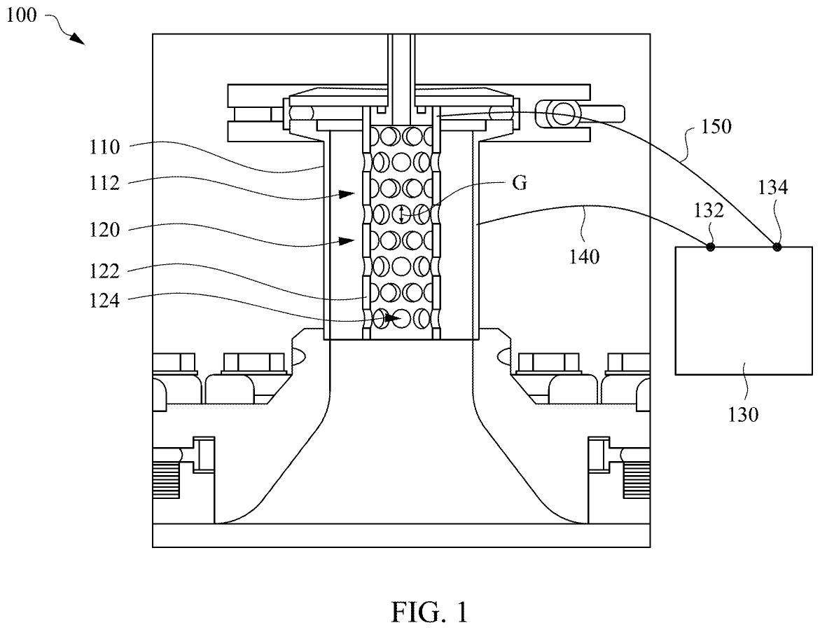

Referring to FIG. 1, FIG. 1 is a schematic cross-sectional view of a plasma device in accordance with one embodiment of the present disclosure. A plasma device 100 may be applied in a plasma coating apparatus, such as a chemical vapor deposition (CVD) apparatus and an atomic layer deposition apparatus. In the present embodiment, the plasma device 100 is a capacitively coupled plasma device. The plasma device 100 may mainly include a hollow chamber casing 110, at least one hollow electrode tube 120, and an intermediate frequency plasma power supply 130. The hollow chamber casing 110 is a conductive casing, and can be used as an electrode of the plasma device 100. The hollow chamber casing 110 has a chamber 112. Plasma is generated in the chamber 112.

The hollow electrode tube 120 is disposed in the chamber 112 of the hollow chamber casing 110. The hollow electrode tube 120 may be, for example, a conductive hollow circular tube. However, the hollow electrode tube 120 may be a conductive hollow oval tube, or a hollow polygonal tube, such as a conductive hollow triangular tube, square tube, or rectangular tube. A material of the hollow electrode tube 120 is conductive material.

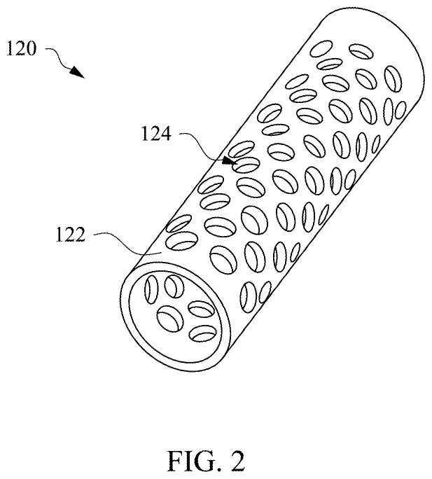

Referring to FIG. 2 simultaneously, FIG. 2 is a three-dimensional schematic diagram showing a hollow electrode tube of a plasma device in accordance with one embodiment of the present disclosure. In the present embodiment, the hollow electrode tube 120 includes many holes 124, in which the holes 124 are perforated in a tube wall 122 of the hollow electrode tube 120. The holes 124 may be of any suitable shape. The shapes of the holes 124 may be identical to each other. Alternatively, the shapes of the holes 124 may be different from each other. Alternatively, the shapes of the holes 124 may not be all the same. The hole 124 may have any shape, as long as it satisfies twice the thickness of the sheath in the plasma generation region is equal to a diameter of the hole 124, that is, a gap G of the internal conductive material, the hollow cathode plasma can be generated. For example, the hole 124 may be a circular, oval, strip-shaped, or irregularly shaped hollow hole. In some exemplary examples, the holes 124 are all circular holes. In some examples, the holes 124 have the same diameter. In other examples, the diameters of the holes 124 may be different from each other. In other examples, the diameters of the holes 124 are not all the same. That is, some of the holes 124 have the same diameter, but not all of the holes 124 have the same diameter. In some exemplary examples, sizes of the holes 124 are about 0.5 mm to about 15 mm. The holes 124 may be arranged in a periodic array or an aperiodic array, and an array of the holes 124 may be a triangular stacking array, a quadrangular stacking array, a pentagonal stacking array, a hexagonal stacking array, etc.

The inductively coupled plasma device must use an expensive radio frequency plasma power supply, so the plasma device 100 of the present disclosure replaces the inductively coupled plasma type with a capacitively coupled plasma type. However, the inventors found that in the technology of the capacitively coupled plasma type, the plasma dissociation rate is not good when using parallel cathode plates. Therefore, the present embodiment uses the hollow electrode tube 120 with the holes 124 as the cathode to effectively increase the density of the plasma generated by the plasma device 100. Accordingly, in the present embodiment, the hollow electrode tube 120 may also be referred as a hollow cathode discharge.

The intermediate frequency plasma power supply 130 has a first potential terminal 132 and a second potential terminal 134. The first potential terminal 132 and the second potential terminal 134 have different potentials. In some examples, a potential of the first potential terminal 132 is greater than a potential of the second potential terminal 134. For example, the first potential terminal 132 is a high voltage output terminal, and the second potential terminal 134 is a ground terminal. In other examples, the potential of the second potential terminal 134 is lower than that of the first potential terminal 132, and a potential difference between the second potential terminal 134 and the first potential terminal 132 can constitute a condition for generating plasma. The first potential terminal 132 of the intermediate frequency plasma power supply 130 is electrically connected to the hollow chamber casing 110, and the second potential terminal 134 is electrically connected to the hollow electrode tube 120. In some exemplary examples, the first potential terminal 132 is connected to the hollow chamber casing 110 through a wire 140, and the second potential terminal 134 is connected to the hollow electrode tube 120 through a wire 150. In some examples, a frequency of the intermediate frequency plasma power supply 130 is about 1 Hz to about 500 kHz.

In some examples, with the combination of the hollow electrode tube 120 and the intermediate frequency plasma power supply 130, the plasma device 100 can form plasma having a plasma density from about 10¹⁰ cm⁻³ to about 10¹¹ cm⁻³. The plasma density of the plasma generated by the capacitively coupled plasma device using parallel cathode plates without holes is only about 10⁸ cm⁻³ to about 10⁹ cm⁻³, the plasma device 100 of the present embodiment has a higher plasma dissociation rate. There is no mutual interference problem between the intermediate frequency plasma power supplies 130, such that plural plasma devices 100 can be set in one coating apparatus at the same time for large-area coating.

According to the aforementioned embodiments, one advantage of the present disclosure is that a plasma device of the present disclosure includes a hollow electrode tube with holes and an intermediate frequency plasma power supply, and can generate a plasma density of about 10¹⁰ cm⁻³ to about 10¹¹ cm⁻³. The price of the intermediate frequency plasma power supply is much lower than that of the radio frequency plasma power supply, such that the plasma device of the present disclosure can greatly reduce the apparatus cost while providing the plasma density similar to that of the inductively coupled plasma device.

Another advantage of the present disclosure is that a plasma device of the present disclosure can generate a plasma density not inferior to that of an inductively coupled plasma device by using an intermediate frequency plasma power supply. There is no mutual interference between the intermediate frequency plasma power supplies, such that the coating apparatus can be equipped with multiple sets of plasma devices at the same time, which is conducive to the enhancement of productivity and suitable for large-area coating.

Although the present disclosure has been disclosed above with embodiments, it is not intended to limit the present disclosure. Any person having ordinary skill in the art can make various changes and modifications without departing from the spirit and scope of the present disclosure. Therefore, the protection scope of the present disclosure should be defined by the scope of the appended claims.

What is claimed is:

1. A plasma device, comprising:
a hollow chamber casing having a chamber;
at least one hollow electrode tube disposed in the chamber, wherein a tube wall of the at least one hollow electrode tube is provided with a plurality of holes; and
an intermediate frequency plasma power supply having a first potential terminal and a second potential terminal, wherein the first potential terminal and the second potential terminal have different potentials, and the first potential terminal and the second potential terminal are respectively connected to the hollow chamber casing and the at least one hollow electrode tube.

2. The plasma device of claim 1, wherein the at least one hollow electrode tube is a hollow cathode discharge.

3. The plasma device of claim 1, wherein the at least one hollow electrode tube comprises a plurality of hollow cathode discharges.

4. The plasma device of claim 1, wherein diameters of the holes are identical.

5. The plasma device of claim 1, wherein diameters of the holes are not all the same.

6. The plasma device of claim 1, wherein shapes of the holes are round, oval, strip, or irregular.

7. The plasma device of claim 1, wherein the at least one hollow electrode tube is made from a conductive material.

8. The plasma device of claim 1, wherein a frequency of the intermediate frequency plasma power supply is 1 Hz to 500 kHz.

9. The plasma device of claim 1, wherein the first potential terminal is a high voltage output terminal, and the second potential terminal is a ground terminal or has a potential lower than a potential of the first potential terminal, which can constitute a condition for generating plasma.

10. The plasma device of claim 1, wherein the plasma device is a capacitively coupled plasma device.

11. A plasma device, wherein the plasma device is a capacitively coupled plasma device, and the plasma device comprises:
a hollow chamber casing having a chamber;
at least one hollow electrode tube disposed in the chamber, wherein a tube wall of the at least one hollow electrode tube is provided with a plurality of holes, and the holes are arranged in an array; and
an intermediate frequency plasma power supply having a first potential terminal and a second potential terminal, wherein the first potential terminal and the second potential terminal have different potentials, the first potential terminal and the second potential terminal are respectively connected to the hollow chamber casing and the at least one hollow electrode tube, and a frequency of the intermediate frequency plasma power supply is 1 Hz to 500 kHz.

12. The plasma device of claim 11, wherein the at least one hollow electrode tube comprises a plurality of hollow cathode discharges.

13. The plasma device of claim 11, wherein diameters of the holes are identical.

14. The plasma device of claim 11, wherein diameters of the holes are ranging from 0.5 mm to 15 mm.

15. The plasma device of claim 11, wherein the array is a periodic array.
